(19) United States
(12) Patent Application Publication
(10) Pub. No.: US 2017/0110647 A1
(43) Pub. Date: Apr. 20, 2017

(54) THERMOELECTRIC DEVICE AND THERMOELECTRIC MODULE, ESPECIALLY INTENDED TO GENERATE AN ELECTRIC CURRENT IN AN AUTOMOTIVE VEHICLE

(71) Applicant: Valeo Systemes Thermiques, Le Mesnil Saint Denis (FR)

(72) Inventor: Cédric DE VAULX, Autouillet (FR)

(73) Assignee: VALEO SYSTEMS THERMIQUES, Le Mesnil Saint Denis (FR)

(21) Appl. No.: 15/301,626

(22) PCT Filed: Apr. 3, 2015
(86) PCT No.: PCT/EP2015/000725

§ 371 Date: Oct. 3, 2016

(30) Foreign Application Priority Data
Apr. 3, 2014 (FR) 1452971

(51) Int. Cl. H01L 35/32; H01L 35/34; H01L 35/08

(52) U.S. Cl. CPC H01L 35/32; H01L 35/08; H01L 35/34; H01L 35/22

(57) ABSTRACT

The invention relates to a thermoelectric device (1) comprising at least two thermoelectric elements (3, 4), called first thermoelectric element and second thermoelectric element, able to generate an electric current owing to the action of a temperature gradient exerted between two of their faces, called first and second active faces (5, 6), the said device comprising a first electrical connection means (21) connecting electrically in series the two thermoelectric elements (3, 4) and a second electrical connection means (22) intended to connect electrically in series one of the two thermoelectric elements (3, 4) of the device with a third thermoelectric element (3, 4), joining of the first electrical connection means (21) and the second electrical connection means (22, 42) together with the first and the second thermoelectric elements (3) being obtained by means of sintering of the said first and second thermoelectric elements.

The invention also relates to a thermoelectric module (20) comprising a plurality of the said thermoelectric devices (1) and a method for manufacturing the device and the module.

The present invention relates to a thermoelectric device and a thermoelectric module comprising such a device, especially intended to generate an electric current in an automotive vehicle.

In the automobile sector, thermoelectric devices using elements, called thermoelectric elements, able to generate an electric current in the presence of a temperature gradient between two of their opposite faces, called active faces, by means of the phenomenon known as the Seebeck effect, have already been proposed. These devices comprise a first circuit, intended for circulation of the exhaust gases of an engine, and a second circuit, intended for the circulation of a heat transfer fluid of a cooling circuit. The thermoelectric elements are arranged between the first and second circuits so as to be subjected to a temperature gradient resulting from the difference in temperature between the exhaust gases, which are hot, and the cooling fluid, which is cold.

The electric modules comprise electric tracks arranged on the active faces of the thermoelectric elements so as to transmit the electricity from an active face of one thermoelectric element to an active face of another thermoelectric element. The electric tracks are assembled on the thermoelectric elements by means of brazing. However, in order to achieve this, it is necessary to heat all the components to high temperatures. But the thermoelectric elements and the electric tracks do not expand in the same way when they are subjected to high temperatures, and the effects of the difference in expansion between the thermoelectric elements and the electrical connection means may thus generate failures in the assemblies.

The invention aims to improve the situation and to this end relates to a thermoelectric device comprising at least two thermoelectric elements, called first thermoelectric element and second thermoelectric element, able to generate an electric current owing to action of a temperature gradient exerted between two of their faces, called first active face and second active face, the said device comprising a first electrical connection means connecting electrically in series the two thermoelectric elements and a second electrical connection means intended to connect electrically in series one of the two thermoelectric elements of the device with a third thermoelectric element, joining of the first electrical connection means and the second electrical connection means together with the first thermoelectric element and the second thermoelectric element being obtained by means of sintering of the said first thermoelectric element and second thermoelectric element.

Thus, as a result of the invention, a thermoelectric device comprising thermoelectric elements and electrical connection means assembled by means of sintering, i.e. without being subject to the stresses associated with assembly by means of brazing, is obtained. The device according to the invention has moreover the advantage of being able to be assembled, in particular by means of the second electrical connection means, to other thermoelectric elements and/or to another thermoelectric device by means of sintering or by means of another assembly method, in particular by means of low-temperature brazing, thus causing less thermal expansion of the electrical connection means, the latter being intended to be situated on the cold side of the temperature gradient.

According to different embodiments of the invention, which may be considered together or singly:
the first active faces are intended to perform heat exchange with a hot source of the temperature gradient and the second active faces are intended to perform heat exchange with a cold source of the temperature gradient in order to generate an electric current;
the first and second active faces are connected together by means of at least one side face, the first electrical connection means electrically connecting together the said side faces, provided opposite each other, of the first and the second thermoelectric elements, and leaving free said active faces;
the said first electrical connection means connects together two parts, situated opposite each other, of the said side faces;
the second electrical connection means is intended to connect electrically another side face of one of the two thermoelectric elements of the device to a side face of the third thermoelectric element;
the first electrical connection means is situated in a zone adjacent to the first or the second active face;
the first electrical connection means cover a first part of the side face of the first and the second thermoelectric elements and the thermoelectric device comprises a first electrically insulating element covering a second part of the said side face of the first and/or the second thermoelectric element.
joining of the first electrically insulating element to the first and/or to the second thermoelectric element is obtained by means of sintering of the said first and/or second thermoelectric elements;
the first electrically insulating element and the first electrical connection means cover the whole of the said side face of the first and/or second thermoelectric element;
the second electrical connection means covers a first part of the said other side face of the said first or second thermoelectric elements and the said thermoelectric device comprises a second electrically insulating element covering a second part of the said other side face;
the second electrical connection means is situated in a zone adjacent to the first or the second active face of the first thermoelectric element or the second thermoelectric element;
joining of the second electrically insulating element to the first thermoelectric element and/or to the second thermoelectric element is obtained by means of sintering of the said first and/or second thermoelectric elements;
the thickness of the first electrical connection means and/or of the second electrical connection means, measured perpendicularly with respect to the side faces, is smaller than 300 micrometers;
the said first electrical connection means electrically connects together the first active faces of the thermoelectric elements of the device and the second electrical connection means being intended to connect electrically the second active face of one of the two thermoelectric elements of the device together with the second active face of the third thermoelectric element;
the first and/or the second thermoelectric element have an annular shape;
the first electrically insulating element and/or the said first electrical connection means have an annular shape;
the said first electrical connection means and the said electrically insulating element are concentric;
the said first electrical connection means is situated straddling an outer peripheral portion or an inner peripheral portion of the said first electrically insulating element. Thus, the first electrical connection means is arranged both on a first side face of the first electrically insulating element in contact with the side face of the first thermoelectric element and on a second side face of the first electrically insulating element in contact with the side face of the second thermoelectric element;
the first active face is defined by an inner peripheral surface and the second active face is defined by an outer peripheral surface;
the first thermoelectric element and the second thermoelectric element are configured so that a difference in electric potential generated by the first thermoelectric element is opposite, in relation to the temperature gradient, to a difference in electric potential generated by the second thermoelectric element;
the first thermoelectric element has a coefficient of thermal expansion equal to Y, the second thermoelectric element has a coefficient of thermal expansion equal to X, X and Y satisfying the relation |Y−X|/X≦15%;
the first electrical connection means has a coefficient of thermal expansion equal to Z₁, X, Y and Z₁ satisfying the relations |Z₁−X|/X≦15% and |Z₁−Y|/Y≦15%;
the second electrical connection means has a coefficient of thermal expansion Z₂, X, Y and Z₂ satisfying the relations |Z₂−X|/X≦15% and |Z₂−Y|/Y≦15%. The coefficient of thermal expansion of the second electrical connection means is, for example, identical to that of the first electrical connection means;
the device is configured so that the said second electrical connection means may be brazed to one of the electrical connection means of an identical device.

The invention also concerns a thermoelectric module comprising a plurality of thermoelectric devices such as those defined above.

According to one aspect of the invention, the plurality of thermoelectric devices are assembled together by means of brazing of two second electrical connection means belonging to two adjacent thermoelectric devices.

According to one example of embodiment, the module comprises a brazing joint for assembling together the plurality of thermoelectric devices, the brazing joint being configured to be brazed at a temperature lower than 300° C.

The invention also relates to a method for manufacturing a thermoelectric device such as that described above, in which the first thermoelectric element and the second thermoelectric element are sintered together so as to join the first electrical connection means and the second electrical connection means together with the said first and second thermoelectric elements.

According to an aspect of the invention, two second electrical connection means of two thermoelectric devices are brazed together.

The invention will be better understood in the light of the following description which is provided purely by way of a non-limiting example, together with the attached drawings in which:

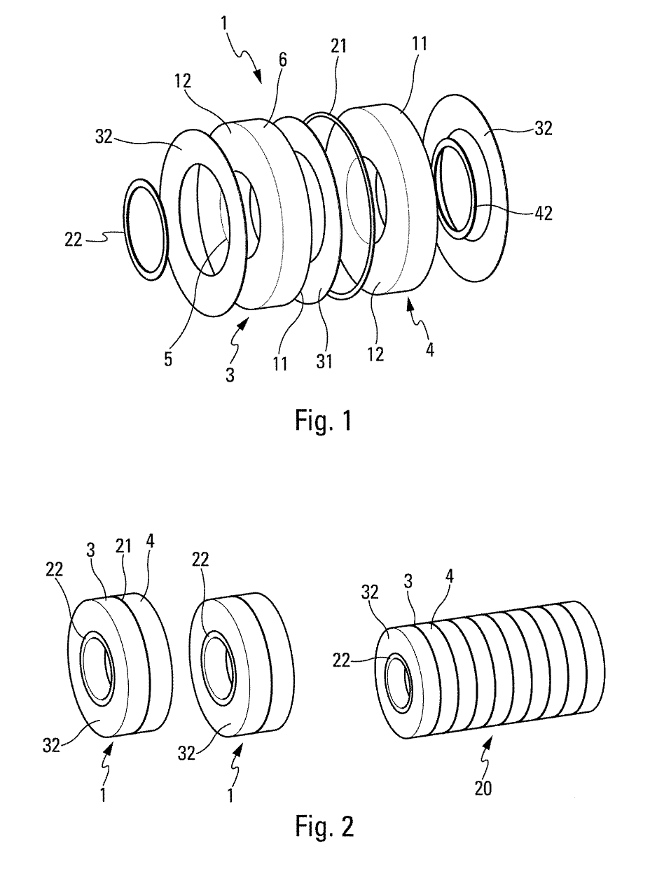

FIG. 1 shows an exploded perspective view of a thermoelectric device according to the invention;

FIG. 2 shows an exploded perspective view of several devices according to FIG. 1 separated from each other and several devices according to FIG. 1 assembled together to form a thermoelectric module according to the invention;

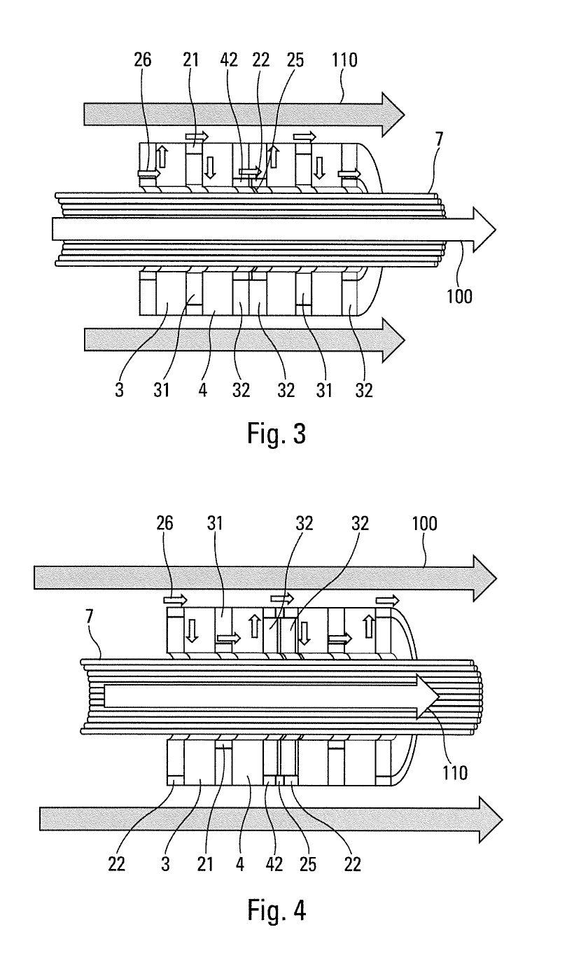

FIGS. 3 and 4 show a schematic view, axially sectioned, of two variations of thermoelectric modules according to the invention;

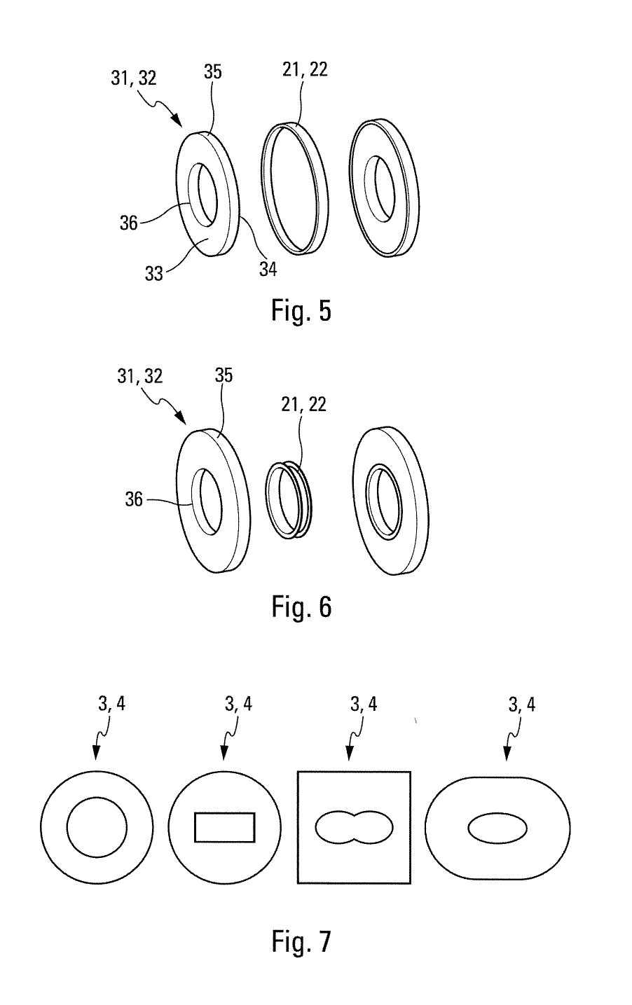

FIGS. 5 and 6 show a schematic perspective view of two variations of embodiment of an assembly consisting of an electrical connection means and an electrical insulation means of a device according to the invention;

FIG. 7 shows a schematic sectioned view of different forms of the thermoelectric element according to the invention.

As shown in FIG. 1, the invention relates to a thermoelectric device 1 comprising a first thermoelectric element 3 and a second thermoelectric element 4 able to generate an electric current owing to the action of a temperature gradient exerted between two of their faces, called active faces 5, 6. A first active face 5 is intended to perform heat exchange with a cold source, for example a heat transfer fluid of a cooling circuit, and a second active face 6 is intended to perform heat exchange with a hot source having a temperature higher than that of the cold source, for example the exhaust gases of an engine. It can be understood here that the temperature gradient allowing operation of the first thermoelectric element is created by the cold source and the hot source.

These thermoelectric elements operate, by means of the Seebeck effect, allowing an electric current to be created in a load connected between the said active faces 5, 6 subjected to the temperature gradient. Such elements are made, for example, of magnesium silicide (Mg₂Si).

The first thermoelectric element 3 is, for example, of a first type, called P, allowing a difference in electrical potential to be established in one direction, called positive, when they are subjected to a given temperature gradient, and, the second thermoelectric element 4 is, in particular of a second type, called N, allowing the creation of a difference in electric potential in an opposite direction, called negative, when they are subjected to the same temperature gradient.

The first thermoelectric element 3 comprises a first side face 11 and a second side face 12. Each of the side faces 11 and 12 connects the first active face 5 to the second active face 6. The sides faces 11, 12 are situated opposite to each other.

In the example of embodiment of the invention shown in the Figures, the first thermoelectric element 3 has an annular shape. The first thermoelectric element 3 is formed here by a ring made as one piece. It may however be formed by several parts each forming an angular portion of the ring.

In the example shown in FIGS. 1 to 3 in which the cold source circulates inside the thermoelectric element 3 and the hot source circulates on the outside of the thermoelectric element 3, the first active face 5 is defined by an inner peripheral surface of the ring and the second active face 6 is defined by an outer peripheral surface of the ring. On the other hand, In the example shown in FIG. 4, the cold source circulates on the outside of the thermoelectric element 3 and the hot source circulates inside the thermoelectric element 3, the first active face 5 being defined by an outer peripheral surface of the ring and the second active face 6 being defined by an inner peripheral surface of the ring.

In both cases, the first and second side faces 11, 12 are flat, in particular parallel to each other, and they extend in particular in planes perpendicular to a central axis of the ring. In other words, the ring forming the thermoelectric element has a rectangular annular cross-section.

The thermoelectric device 1 comprises a first electrical connection means 21 connecting electrically in series the first thermoelectric element 3 to the second thermoelectric element 4.

The thermoelectric device 1 according to the invention also comprises a second electrical connection means 22, 42 intended to connect electrically in series the second thermoelectric element 4 to a third thermoelectric element 3, 4 belonging in particular to an adjacent thermoelectric device 1 with the aim of forming an electric thermomodule according to the invention. The second thermoelectric element 4 in particular has a shape similar to that of the first thermoelectric element 3.

According to the invention, the first thermoelectric element 3, the second electric element 4, the first electrical connection means 21 and the second electrical connection means 22, 42 are assembled together by means of sintering. It is understood thereby that it is the operation of sintering the material intended to form the first and second thermoelectric elements which ensures joining of the latter together with the first and second electrical connection means which for their part are pre-formed, in particular in the form of metal tracks.

The sintering increases the cohesion between the powder particles which form the thermoelectric elements 3, 4, but also between the thermoelectric elements 3, 4 and the electrical connection means 21, 22 ensuring also reduction to a minimum of the electrical contact resistances.

The first electrical connection means 21 is arranged here on a first part of the first side face 11 of the first thermoelectric element 3 and electrically connects in series the first thermoelectric element 3 to the second side face 12 of the second thermoelectric element 4. The second electrical connection means 22, 42 is arranged on the second side face 12 of the first thermoelectric element 3 connecting its first active face 5 to its second active face 6, or on the first side face 11 of the second thermoelectric element 4 connecting its first active face 5 to its second active face 6. The thermoelectric device according to the invention may also comprise two second electrical connection means, one 22 of which is arranged on the second side face 12 of the first thermoelectric element 3 connecting its first active face 5 to its second active face 6, and the other one 42 of which on the first side face 11 of the second thermoelectric element 4 connecting its first active face 5 to its second active face 6.

The arrangement of the first and second electrical connection means 21, 22, 42 leaves free here the active faces 5, 6 of the said first and second thermoelectric elements 3, 4. This arrangement on the side surface of the thermoelectric elements thus allows decoupling of the heat exchange from the electrical exchange and prevents the electrical connection means from acting as a heat screen between the active faces of the thermoelectric element, receiving the temperature gradient and the cold and hot sources creating this gradient.

Advantageously, in the case where the thermoelectric elements 3, 4 are annular, the first electrical connection means 21 is also annular.

The first part of the first side face 11 on which the first connection means 21 is located is a part adjacent to the second active face 6, i.e. a part adjacent to the hot source.

In this case, the second electrical connection means 22, 42 is/are situated on a first part of the side face where they are adjacent to the first active face 6, i.e. a part adjacent to the cold source.

The method of assembly by means of sintering is in fact particularly advantageous when the first electrical connection means 21 is situated close to the hot source, i.e. here close to the second active face 6 of the first and the second thermoelectric elements. In fact, assembly by means of sintering is less stressful for the thermoelectric elements than high-temperature brazing and moreover resists the very high temperatures of the hot source, in particular in the case where it consists of exhaust gases, this not always being the case of brazing joints. The invention is thus able to limit the risk of failure of the assembly due to the high operating temperature of the hot source.

The thermoelectric device 1 according to the invention may be assembled with other similar devices 1 to form a thermoelectric module 20, as shown in FIGS. 2 to 4 such that the current may circulate in series between the adjacent thermoelectric devices 1 and between the adjacent thermoelectric elements 3, 4.

It is the alternating arrangement of the first electrical connection means 21 close to the second active face 6 and of the second electrical connection means 22 close to the first active face 5 which allows the circulation of the current in series between two adjacent thermoelectric elements of different types in the direction of the arrows 26 shown in FIGS. 3 and 4.

This thus gives rise to a thermoelectric module 20 in which the said thermoelectric elements 3, 4 are arranged, for example, in the longitudinal extension of each other, in particular coaxially, and the thermoelectric elements of type P alternate with the thermoelectric elements of type N in a direction parallel to a longitudinal axis of the module. In particular, they have an identical shape and size. They may, however, have a thickness, i.e. a dimension between their side faces, provided flat here, which is different from one type to another, in particular depending on their electrical conductivity.

Assembly of two thermoelectric devices 1 is performed advantageously by means of the two electrical connection means 22, 42 of each device as shown in FIGS. 3 and 4.

As seen above, the part on which the second electrical connection means 22 is situated is far from the hot source and therefore is not subject to very high temperatures. Assembly of two adjacent thermoelectric devices 1 by means of the two electrical connection means 22 may therefore be performed by a brazing method carried out at a low temperature, i.e. at a temperature lower than 300° C. Brazing is performed between the second electrical connection means 22, 42 of a thermoelectric device 1 and the second electrical connection means 22, 42 of an adjacent thermoelectric device 1, in particular with the aid of a brazing joint 25. The brazing joint is configured to allow brazing at a temperature lower than 300° C. With this cold brazing method it is possible to avoid subjecting the electrical connection means 21, 22 and the thermoelectric elements 3, 4 to very high temperatures which are reached with hot brazing and which would cause significant thermal expansion followed by retraction resulting in particular in weakening of the mechanical links between the electrical connection means 21, 22 and the thermoelectric elements 3, 4. This method of assembly is all the more interesting since it uses less energy than a high-temperature brazing method which requires the use of a large amount of energy.

The invention is thus able to use a sintering method for assembly of the first electrical connection means and the second electrical connection means with the thermoelectric elements, followed by cold brazing for assembly of the second electrical connection means with other second electrical connection means, avoiding use of the hot brazing method.

In the example of embodiment shown in FIG. 3, the cold fluid circulates inside the thermoelectric elements 3, 4 as indicated by the arrow 100, while the hot fluid circulates on the outside of the thermoelectric elements as indicated by the arrow 110. The first electrical connection means 21 are therefore situated here in the region of an outer peripheral zone of the side faces 11, 12 on which they are located. The second electrical connection means 22 are situated in the region of an internal peripheral zone of the side faces 11, 12 on which they are located.

Conversely, in the example of embodiment shown in FIG. 4, the cold fluid circulates on the outside of the thermoelectric elements 3, 4 as indicated by the arrow 100, while the hot fluid circulates inside the thermoelectric elements as indicated by the arrow 110. The first electrical connection means 21 are therefore situated here in the region of an inner peripheral zone of the side faces 11, 12 on which they are located. The second electrical connection means 22 are situated in the region of an outer peripheral zone of the side faces 11, 12 on which they are located.

For circulation of the fluids, the module according to the invention may comprise a duct 7 for circulation of fluid inside the said thermoelectric elements 3, 4. The said liquid circulation ducts(s) 7 have, for example, a circular cross-section.

The thermoelectric device 1 according to the invention may comprise a first electrically insulating element 31 covering a second part of the side face on which the first electrical connection means 21 is located. Advantageously, the first electrically insulating element 31 and the first electrical connection means 21 cover all of the said first side face of the first thermoelectric element 21, in particularly concentrically.

The first electrically insulating element 31 is assembled on the first thermoelectric element 3 by means of sintering. It may also be assembled on the second thermoelectric element 4 by means of sintering during assembly of the thermoelectric device 1.

As shown in FIGS. 5 and 6, when the first electrically insulating element 31 has an annular shape, the said first electrical connection means 21 may be situated straddling an outer peripheral portion 35 or an inner peripheral portion 36 of the first electrically insulating element 31 so as to be arranged both on a first side face 33 of the first electrically insulating element 31 in contact with the first thermoelectric element and on a second side face 34 of the first electrically insulating element 31 intended to be in contact with the second side face of the second thermoelectric element. The first electrical connection means 21 has, for this purpose, a U-shaped cross-section.

As can be seen in FIG. 1, the thermoelectric device 1 according to the invention further comprises a second electrically insulating element 32 covering a second part of the side face on which the second electrical connection means is located. The second connection means 22 is assembled on the first thermoelectric element or on the second electric element, in particular by means of sintering.

In the same manner as the first electrical connection means 21 and the first electrically insulating element 31, the second electrical connection means 22 and the second electrically insulating element 32 cover advantageously the whole of the side face on which they are located, in particular concentrically.

In the same way as the first electrical connection means 21, the said second electrical connection means 22 may be situated straddling an outer peripheral portion 35 or an inner peripheral portion 36 of the second electrically insulating element 32 so as to be arranged both on a first side face 33 of the second electrically insulating element 32 in contact with the first or the second thermoelectric element and on a second side face 34 of the second electrically insulating element 32 intended to make contact, after low temperature brazing, with the side face of a second electrical connection means of an adjacent thermoelectric device 1. The second electrical connection means 22 has, for this purpose, a U-shaped cross-section.

It may be noticed that when the first electrical connection means 21 of a thermoelectric device 1 is located on the outer periphery of the first electrically insulating element 31, the second electrical connection means 22 of the same thermoelectric device 1 is located on the inner periphery of the second electrically insulating element 31 belonging to the same thermoelectric device 1 and vice versa.

FIG. 7 shows different embodiments of the invention in which the outer geometrical form and/or the inner geometrical form of the thermoelectric elements 3, 4 change in order to adapt in the best possible manner to the dimensional constraints of the thermoelectric module while ensuring good efficiency of the thermoelectric module.

The outer and/or inner forms of the said thermoelectric elements will be, for example, circular, quadrilateral, oval or a combination of these different forms.

Advantageously, the first thermoelectric element 3 has a coefficient of thermal expansion equal to Y, the second thermoelectric element 4 has a coefficient of thermal expansion equal to X, X and Y satisfying the relation |Y−X|/X≦15%. The first electrical connection means 21 and the second electrical connection means 22 may moreover have coefficients of thermal expansion equal to Z₁ and Z₂, X, Y, Z₁, Z₂, satisfying the relations |Z₁−X|/X≦15% and |Z₁−Y|/Y≦15% and |Z₂−X|/X≦15% and |Z₂−Y|/Y≦15%. The small difference in the coefficient of thermal expansion between the first thermoelectric element 3 and the second thermoelectric element 4 on the one hand and between the electrical connection means 21, 22 and the thermoelectric elements 3, 4 on the other hand is such that the sintering together of these elements may be improved, in particular improving the mechanical strength of the device 1 once assembled.

The first electrical connection means 21 and the second electrical connection means 22 are, in particular, made of the same material. In the same way, the first and the second electrically insulating elements are, in particular, made of the same material.

The invention also relates to an embodiment, although not illustrated, in which the first electrical connection means 21 electrically connects together the first active faces 5 of the thermoelectric elements 3,4 of the device 1 and the second electrical connection means 22 is intended to connect electrically the second active face 6 of one of the two thermoelectric elements of the device together with the second active face 6 of another thermoelectric element.

1. A thermoelectric device comprising:
at least two thermoelectric elements, called a first thermoelectric element and a second thermoelectric element, able to generate an electric current owing to the action of a temperature gradient exerted between two faces of the first and second thermoelectric elements, called first active face and second active face; and
a first electrical connection means connecting electrically in series the first and second thermoelectric elements and a second electrical connection means intended to connect electrically in series one of the first and second thermoelectric elements of the device with a third thermoelectric element,
wherein the first electrical connection means and the second electrical connection means are joined together with the first thermoelectric element and the second thermoelectric element by sintering of the first and second thermoelectric elements.

2. The thermoelectric device as claimed in claim 1, wherein
the first active faces are intended to perform heat exchange with a hot source of the temperature gradient and the second active faces are intended to perform heat exchange with a cold source of the temperature gradient in order to generate an electric current, and
the first active faces and second active faces are connected together by at least one side face, the first electrical connection means electrically connecting together the side faces, provided opposite each other, of the first thermoelectric element and the second thermoelectric element and leaving free said active faces.

3. The thermoelectric device as claimed in claim 2, wherein the second electrical connection means is intended to connect electrically another side face of one of the two thermoelectric elements of the device to a side face of the third thermoelectric element.

4. The thermoelectric device as claimed in claim 2, wherein the first electrical connection means is situated in a zone adjacent to the first active face or the second active face.

5. The thermoelectric device as claimed in claim 2, wherein the first electrical connection means covers a first part of the side face of the first and the second thermoelectric elements and the thermoelectric device comprises a first electrically insulating element covering a second part of the side face of the first thermoelectric element and/or the second thermoelectric element.

6. The thermoelectric device as claimed in claim 5, wherein joining of the first electrically insulating element to the first thermoelectric element and/or to the second thermoelectric element is obtained by sintering of the first and/or second thermoelectric elements.

7. The thermoelectric device as claimed in claim 5, wherein the first electrically insulating element and the first electrical connection means cover the whole of the side face of the first and/or the second thermoelectric element.

8. The thermoelectric device as claimed in claim 5, wherein the first electrical connection means is situated straddling an outer peripheral portion or an inner peripheral portion of the first electrically insulating element.

9. The thermoelectric device as claimed in claim 3, wherein the second electrical connection means covers a first part of the other side face of the first or second thermoelectric elements and the thermoelectric device comprises a second electrically insulating element covering a second part of the other side face.

10. The thermoelectric device as claimed in claim 9, wherein the second electrical connection means is situated in a zone adjacent to the first or the second active face of the first thermoelectric element or the second thermoelectric element.

11. The thermoelectric device as claimed in either claim 9, wherein joining of the second electrically insulating element to the first thermoelectric element and/or to the second thermoelectric element is obtained by means of sintering of the first and/or second thermoelectric elements.

12. The thermoelectric device as claimed in claim 2, wherein the thickness of the first electrical connection means and/or of the second electrical connection means, measured perpendicularly with respect to the side faces, is less than 300 micrometers.

13. The thermoelectric device as claimed in claim 1, wherein the first and/or the second thermoelectric elements have an annular shape.

14. The thermoelectric device as claimed in claim 13, wherein the first active face is defined by an inner peripheral surface and the second active face is defined by an outer peripheral surface.

15. The thermoelectric device as claimed in claim 1, wherein the device is configured so that the second electrical connection means may be brazed to one of the electrical connection means of an identical device.

16. A thermoelectric module comprising a plurality of thermoelectric devices as claimed in claim 1.

17. The thermoelectric module as claimed in claim 16, wherein the plurality of thermoelectric devices are assembled together by means of brazing of two second electrical connection means belonging to two adjacent thermoelectric devices.

18. A method for manufacturing a thermoelectric device as claimed in claim 1, comprising:
sintering together the first thermoelectric element and the second thermoelectric element so as to join the first electrical connection means and the second electrical connection means together with the first and second thermoelectric elements.

19. The method for manufacturing a thermoelectric module as claimed in claim 18, wherein:
two second electrical connection means of two thermoelectric devices are brazed together.
